(19) United States
(12) Patent Application Publication
(10) Pub. No.: US 2005/0205585 A1
(43) Pub. Date: Sep. 22, 2005

(54) Compound container

(76) Inventor: Hsiang-Hua Chiu Huang, Tainan (TW)

Correspondence Address: Hsiang-Hua CHIU HUANG, P.O. Box 6-9, Tainan, TW

(21) Appl. No.: 10/803,654

(22) Filed: Mar. 16, 2004

(51) Int. Cl. H01L 29/76

(52) U.S. Cl. 220/643

(57) ABSTRACT

A compound container includes a body made of a transparent material, a metal ring fixed tightly and covering an upper open end of the body, and a metal base adhered under the bottom of the body by means of high frequency. Then the compound container presents a pretty appearance of brilliancy of the metal ring and the metal base and transparency of the body and their color diversity, upgrading efficiency for displaying and using and worth as merchandise.

### BCACKGROUND OF THE INVENTION

1. Field of the Invention

This invention relates to a compound container, particularly to one having a body made of a transparent material, a metal ring made of stainless steel and fixed closely around an upper end of a container with no gaps between the metal ring the container body, and a metal base also made of stainless steel and adhered under the bottom of the body, enhanced in its whole beauty and worth,

2. Description of the Prior Art

Traditional common containers such as cups, dishes, plates bowls used in dinnerware are generally colored with only one, devoid of various colors. So some containers are colored with patterns or pictures by means of screen-printing to augment their beauty to try to attract people's attention. But they may look monotonous and not dimensional, with the pattern or the picture printed or adhered on the outer surface but liable to wane gradually or peel off owing to frequent alteration of temperature and wetness to cause damage to their beauty.

A conventional compound container 1 shown in FIGS. 1 and 2 includes a body 10, a metal ring 11 fixed around an upper open end of the body 10, and a metal base 12 fixed under the bottom of the body 10. This conventional container 1 has a disadvantage that the metal ring 11 and the metal base 12 may become loose and rotate, and a large gap may arise between the metal ring 11 and the body 10 and between the metal bottom 12 and the body 10 for miscellaneous matter to fill therein, degrading the worth and acceptability of the conventional compound container 1.

### SUMMARY OF THE INVENTIOIN

This invention has been devised to offer a compound container having a body made of a transparent material, and a metal ring and a metal base both made of stainless steel to make it look pretty and worthy with the transparency of the body and the brilliancy of the metal ring and the metal base and their color diversity.

The feature of the invention is a metal ring fixed around the upper open end and a metal base fixed under the bottom of the body, with no gap formed between the metal ring or the metal bottom and the container body.

### BRIEF DESCRIPTION OF DRAWINGS

This invention will be better understood by referring to the accompanying drawings, wherein:

FIG. 1 is an exploded perspective view of a conventional compound container;

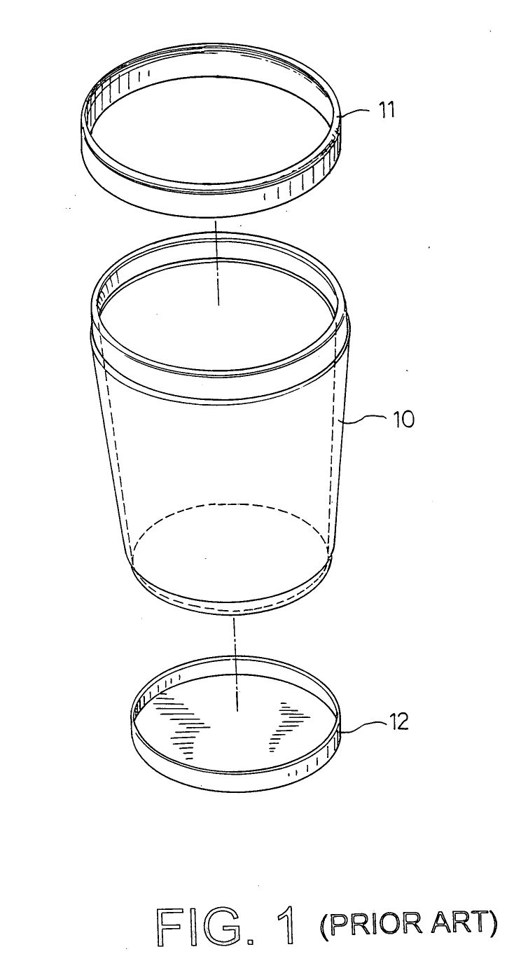

FIG. 2 is a cross-sectional view of the conventional compound container;

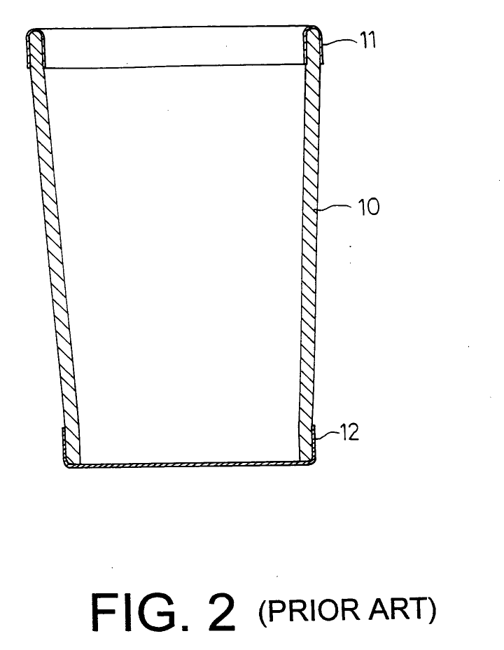

FIG. 3 is an exploded perspective view of a compound container in the present invention;

FIG. 4 is a perspective view of the compound container in the present invention; and,

FIG. 5 is a cross-sectional view of the compound container in the present invention.

### DETAILED DESCRIPTION OF THE PREFERRED EMBODIMENT

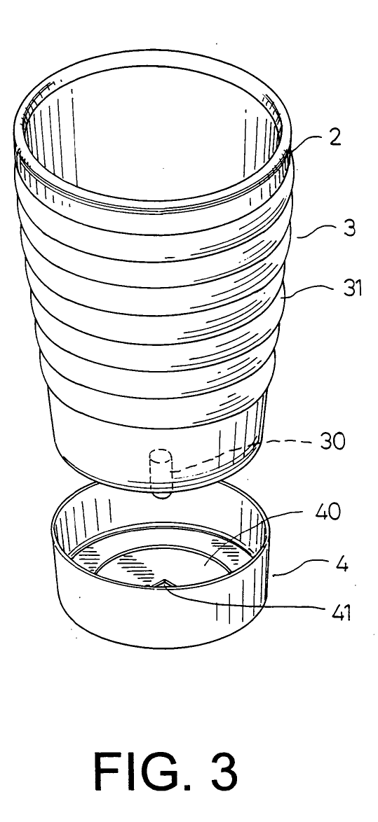

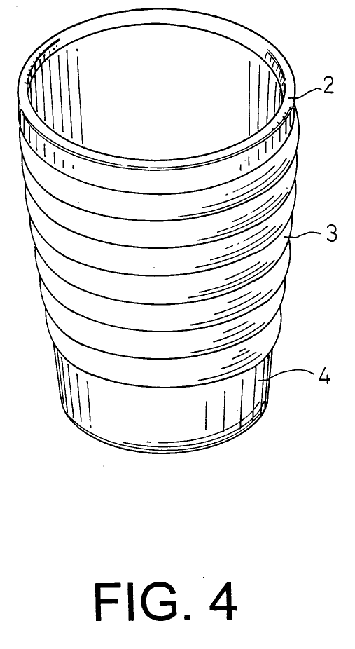

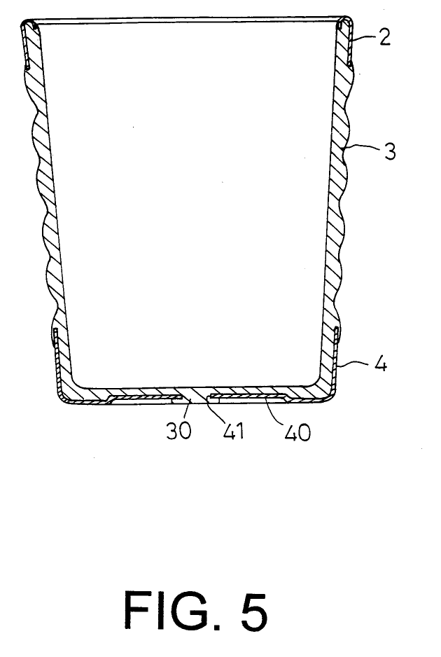

A preferred embodiment of a compound container in the present invention, as shown in FIGS. 3, 4 and 5, includes a body 3, a metal ring 2, and a metal base 4 as main components combined together

The body 3 is made of a transparent material, having a post-like projection 30 extending down from the center of the bottom of the body 3, a plurality of annular wave-like strips 31 continually formed on an intermediate outer surface of the body 3.

The metal ring 3 is made of stainless steel, fixed firmly and covering around the upper open end of the body 3.

The metal base 4 is made of stainless steel, fixed under the lower side of the bottom of the body 3, shaped as a saucer and having a shallow recess 40 for placing an anti-slip sheet thereon, and a multi-angled hole 41 bored in the center of the recess 40.

In assembling, at first, the metal ring is fixed tightly and covering around the upper open end of the body. Next, the metal base 4 is placed under the bottom of the body 3, with the post-like projection 30 fitted in the multi-angled hole 41 firmly. Then the body 3 and the metal base 4 are adhered together by means of high frequency, with the post-like projection 30 stably fixed in the multi-angled hole 41, finishing assembling of the compound container.

The compound container in the invention has the following advantages, as can be understood from the aforesaid description.
1. It is made of different materials of different colors, with the metal ring 2 and the metal base 4 of stainless steel completely assembled with the body 3 of a transparent material, augmenting its whole beauty with the brilliancy of the two metal components and the transparency of the body 3, enhanced in economic value as merchandise.
2. The metal ring 2 is fixed tightly enough around the upper open end of the body 3 and covering on it, impossible to loosen a bit or to have any gap relative to the body 3.
3. The metal base 4 and the body 3 are adhered together by means of high frequency to let the post-like projection 30 utterly engaging with the multi-angled hole 41, preventing the metal base 4 from loosening to rotate in any way.

While the preferred embodiment of the invention has been described above, it will be recognized and understood that various modifications may be made therein and the appended claims are intended to cover all such modifications that may fall within the spirit and scope of the invention.

1. A compound container comprising a body made of a transparent material, a metal ring made of stainless steel and fixed tightly and covering around an upper open end of said body, a metal base adhered under a lower side of the bottom of said body by means of high frequency, said container looking pretty by the brilliancy of said metal ring and of said metal base and the transparency of said body and their color diversity.

2. The compound container as claimed in claim 1, wherein said metal base has a multi-angled hole in the center of the bottom, said post-like projection of the bottom of said body fitting securely in said multi-angled hole of said metal base so that the combination of said body and said metal base is tight, not letting said metal base rotate a bit.

3. The compound container as claimed in claim 1, wherein said metal base has a shallow recess formed in an upper surface of the bottom, and an anti-slip sheet is adhered on said shallow recess for keeping said body to be positioned stably thereon.

4. The compound container as claimed in claim 1, wherein said container is shaped as a cup, a bottle, a jar, a saucer, a dish, a plate, a can or a pail.
